(19) United States
(12) Patent Application Publication
(10) Pub. No.: US 2025/0221132 A1
(43) Pub. Date: Jul. 3, 2025

(54) Stretchable Display Device and Method of Manufacturing the Same

(71) Applicant: LG Display Co., Ltd., Seoul (KR)

(72) Inventor: Do-Joong Kim, Paju-si (KR)

(21) Appl. No.: 18/962,100

(22) Filed: Nov. 27, 2024

(30) Foreign Application Priority Data
Dec. 28, 2023 (KR) 10-2023-0195417

(51) Int. Cl. H10H 29/80; H10H 29/01

(52) U.S. Cl. CPC H10H 29/8321; H10H 29/032; H10H 29/8323

(57) ABSTRACT

A stretchable display device includes a base substrate having a rigid portion and a soft portion; a stretchable line in the soft portion over the base substrate; a first electrode and a second electrode in the rigid portion over the base substrate; and a light-emitting element contacting the first electrode and the second electrode, wherein the first electrode and the second electrode have a plurality of first protrusions and a plurality of second protrusions, and the light-emitting element is in contact with the plurality of first protrusions and the plurality of second protrusions.

### CROSS-REFERENCE TO RELATED APPLICATION

The present application claims priority to Republic of Korea Patent Application No. 10-2023-0195417 filed on Dec. 28, 2023, which is hereby incorporated by reference in its entirety.

### BACKGROUND

### Field of the Disclosure

The present disclosure relates to a display device, and more particularly, to a stretchable display device and a method of manufacturing the same.

### Discussion of the Background Art

As the information society progresses, interest in displays that process and display a large amount of information has been increasing, and various types of displays have been developed.

Accordingly, in addition to a commonly known rectangular display, flexible display devices such as a bendable display device for gaming, a foldable display device capable of being folded and unfolded, and a rollable display device having optimal space utilization have been widely developed.

Recently, a stretchable display device, which is much more flexible than these flexible display devices, has been in the spotlight as a next-generation display.

The stretchable display device is a display that can freely transform the shape of a screen without distortion even when the size of the screen is increased, folded, or twisted. Unlike the bendable, foldable, or rollable display devices that can only be transformed in a specific area or direction, the stretchable display device is able to implement the ultimate free-form and is considered as the most suitable display for the era of the Internet of Things (IoT), 5G, and autonomous vehicles.

The stretchable display device may include a rigid portion in which a pixel is disposed and a soft portion in which a connection line connecting the pixels is disposed. The rigid portion may not be stretched, and the soft portion may be stretched.

To display an image, the stretchable display device includes a light-emitting element in the rigid portion, and an anisotropic conductive film (ACF) may be used to fix and electrically connect the light-emitting element. The anisotropic conductive film may include an insulating base member and a plurality of conductive balls dispersed in the insulating base member. Since two electrodes are electrically connected via the conductive balls in an area where heat or pressure is applied, the contact resistance between the two electrodes is relatively high, so that the electrical properties of the light-emitting element can deteriorate due to problems such as overheating.

In addition, the anisotropic conductive film is provided all over the rigid portion and is formed even in areas where it is not needed, so that the manufacturing costs can increase.

### SUMMARY

Accordingly, the present disclosure is to provide a stretchable display device and a method of manufacturing the same that substantially obviates one or more of the limitations and disadvantages described above and associated with the background art.

More specifically, an object of the present disclosure is to provide a stretchable display device including a light-emitting element with the improved electrical properties and a method of manufacturing the same.

Another object of the present disclosure is to provide a stretchable display device and a method of manufacturing the same capable of reducing the manufacturing costs.

Additional features and aspects will be set forth in the description that follows, and in part will be apparent from the description, or can be learned by practice of the present disclosure provided herein. Other features and aspects of the inventive concepts can be realized and attained by the structure particularly pointed out in the written description, or derivable therefrom, and the claims hereof as well as the appended drawings.

To achieve these and other embodiments of the present disclosure, as embodied and broadly described herein, a stretchable display device includes a base substrate having a rigid portion and a soft portion; a stretchable line in the soft portion over the base substrate; a first electrode and a second electrode in the rigid portion over the base substrate; and a light-emitting element contacting the first electrode and the second electrode, wherein the first electrode and the second electrode have a plurality of first protrusions and a plurality of second protrusions, and the light-emitting element is in contact with the plurality of first protrusions and the plurality of second protrusions.

In another embodiment, a method of manufacturing a stretchable display device includes preparing a base substrate having a rigid portion and a soft portion; forming a stretchable line in the soft portion over the base substrate; forming a first electrode and a second electrode in the rigid portion over the base substrate; and transferring a light-emitting element contacting the first electrode and the second electrode, wherein forming the first electrode and the second electrode includes forming a plurality of first protrusions and a plurality of second protrusions, and wherein transferring the light-emitting element includes contacting the light-emitting element with the plurality of first protrusions and the plurality of second protrusions.

It is to be understood that both the foregoing general description and the following detailed description are examples and are intended to provide further explanation of the inventive concepts as claimed.

### BRIEF DESCRIPTION OF THE DRAWINGS

The accompanying drawings, which are included to provide a further understanding of the present disclosure and which are incorporated in and constitute a part of this application, illustrate aspects of the disclosure and together with the description serve to explain various principles of the present disclosure.

In the drawings:

FIG. 1 is a schematic cross-sectional view of a stretchable display device according to an embodiment of the present disclosure;

FIG. 2 is a schematic plan view of a display panel of a stretchable display device according to an embodiment of the present disclosure;

FIG. 3 is a plan view schematically illustrating a part of a display panel of a stretchable display device according to an embodiment of the present disclosure;

FIG. 4 is a view schematically showing a manufacture procedure of a stretchable display device according to an embodiment of the present disclosure;

FIG. 5 is an equivalent circuit diagram for a sub-pixel of a stretchable display device according to an embodiment of the present disclosure;

FIG. 6 is a schematic cross-sectional view of a stretchable display device according to an embodiment of the present disclosure;

FIG. 7 is a schematic plan view of a pixel structure of a stretchable display device according to an embodiment of the present disclosure;

FIGS. 8A to 8I are schematic cross-sectional views of a display panel in steps of manufacturing a stretchable display device according to a first embodiment of the present disclosure;

FIGS. 9A to 9C are schematic cross-sectional views of a display panel in steps of manufacturing a stretchable display device according to a second embodiment of the present disclosure;

FIGS. 10A to 10E are schematic cross-sectional views of a display panel in steps of manufacturing a stretchable display device according to a third embodiment of the present disclosure.

### DETAILED DESCRIPTION

Advantages and features of the present disclosure and methods for achieving them will be made clear from embodiments described in detail below with reference to the accompanying drawings. The present disclosure can, however, be implemented in many different forms and should not be construed as being limited to the embodiments set forth herein, and the embodiments are provided such that this disclosure will be thorough and complete and will fully convey the scope of the present disclosure to those skilled in the art to which the present disclosure pertains.

Shapes, sizes, ratios, angles, numbers, and the like disclosed in the drawings for describing the embodiments of the present disclosure are illustrative, and thus the present disclosure is not limited to the illustrated matters. The same reference numerals refer to the same components throughout this disclosure. Further, in the following description of the present disclosure, when a detailed description of a known related art is determined to unnecessarily obscure the gist of the present disclosure, the detailed description thereof will be omitted herein or may be briefly discussed.

When terms such as “including,” “having,” “comprising” and the like mentioned in this disclosure are used, other parts can be added unless the term “only” is used herein. Further, when a component is expressed as being singular, being plural is included unless otherwise specified.

In analyzing a component, an error range is interpreted as being included even when there is no explicit description.

In describing a positional relationship, for example, when a positional relationship of two parts/layers is described as being “over,” “on,” “above,” “below,” “under,” “next to,” or the like, one or more other parts/layers can be provided between the two parts/layers, unless the term “immediately” or “directly” is used therewith.

In describing a temporal relationship, for example, when a temporal predecessor relationship is described as being “after,” “subsequent,” “next to,” “prior to,” or the like, unless “immediately” or “directly” is used, cases that are not continuous or sequential can also be included.

Although the terms first, second, and the like are used to describe various components, these components are not substantially limited by these terms. These terms are used only to distinguish one component from another component, and may not define any order or sequence. Therefore, a first component described below can substantially be a second component within the technical spirit of the present disclosure.

Features of various embodiments of the present disclosure can be partially or entirely united or combined with each other, technically various interlocking and driving are possible, and each of the embodiments can be independently implemented with respect to each other or implemented together in a related relationship.

Hereinafter, exemplary embodiments of the present disclosure will be described in detail with reference to accompanying drawings.

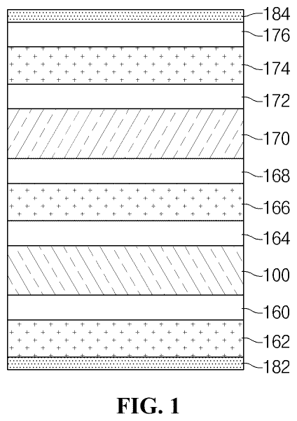

FIG. 1 is a schematic cross-sectional view of a stretchable display device according to an embodiment of the present disclosure.

In FIG. 1, a stretchable display device according to an embodiment of the present disclosure may include a display panel 100, a touch panel 170, a first flexible substrate 162, a second flexible substrate 166, a third flexible substrate 174, a first protection film 182, and a second protection film 184.

The display panel 100 may display an image and may include a rigid portion provided with a pixel for implementing the image and a soft portion provided with a connection line connecting adjacent pixels, which will be described in detail later.

The first flexible substrate 162 may be disposed under the display panel 100 and may be provided with a first adhesive layer 160 to thereby have a double film shape. The display panel 100 may be attached to the first flexible substrate 162 through the first adhesive layer 160. In addition, the second flexible substrate 166 may be disposed over the display panel 100 and may be provided with a second adhesive layer 164 at its bottom surface and a third adhesive layer 168 at its top surface to thereby have a triple film shape. The display panel 100 may be attached to the second flexible substrate 166 through the second adhesive layer 164.

The first flexible substrate 162 and the second flexible substrate 166 may be formed of a soft matter or soft material with bending or stretching properties. For example, the first flexible substrate 162 and the second flexible substrate 166 may be formed of silicone rubber such as polydimethylsiloxane (PDMS), elastomer such as polyurethane (PU), or styrene butadiene block copolymer such as styrene butadiene styrene (SBS).

The first flexible substrate 162 and the second flexible substrate 166 may be formed of the same material. However, embodiments of the present disclosure are not limited thereto. In other embodiments, the first flexible substrate 162 and the second flexible substrate 166 may be formed of different materials.

The first flexible substrate 162 and the second flexible substrate 166 may have relatively low elastic modulus, that is, Young's modulus, and may have a relatively high ductile breaking rate. Here, the elastic modulus is a value representing the rate of deformation relative to the stress applied to an object. If the elastic modulus is relatively high, the hardness may be relatively high. In addition, the ductile breaking rate refers to the elongation rate at the point when the stretched object is broken or cracked.

For example, each of the first flexible substrate 162 and the second flexible substrate 166 may have the elastic modulus of several MPa to hundreds of MPa and the ductile breaking rate of about 100% or more. In addition, each of the first flexible substrate 162 and the second flexible substrate 166 may have a thickness of about 10 μm to about 1 mm. However, embodiments of the present disclosure are not limited thereto.

Meanwhile, the first, second, and third adhesive layers 160, 164, and 168 may be formed of an acryl-based, silicon-based, or urethane-based adhesive. For example, the first, second, and third adhesive layers 160, 164, and 168 may be optically clear adhesive (OCA) that is formed and attached in the form of a film or optically clear resin (OCR) that is cured after applying a liquid material.

Next, the touch panel 170 may be disposed over the second flexible substrate 166 and may be attached to the second flexible substrate 166 through the third adhesive layer 168.

The touch panel 170 may include a plurality of transmitter electrodes and a plurality of receiver electrodes and may detect a touch from a change in capacitance between the transmitter electrode and the receiver electrode.

The third flexible substrate 174 may be disposed over the touch panel 170 and may be provided with a fourth adhesive layer 172 at its bottom surface and a fifth adhesive layer 176 at its top surface. The touch panel 170 may be attached to the third flexible substrate 174 through the fourth adhesive layer 172.

The third flexible substrate 174 may be formed of the same material as the first and second flexible substrates 162 and 166, and the fourth and fifth adhesive layers 172 and 176 may be formed of the same material as the first, second, and third adhesive layers 160, 164, and 168.

The first protection film 182 may be disposed under the first flexible substrate 162, and the second protection film 184 may be disposed over the third flexible substrate 174, thereby protecting the components of the stretchable display device. The second protection film 184 may be attached to the third flexible substrate 174 through the fifth adhesive layer 176, and although not shown in the figure, an adhesive layer may be provided and attached between the first flexible substrate 162 and the first protection film 182.

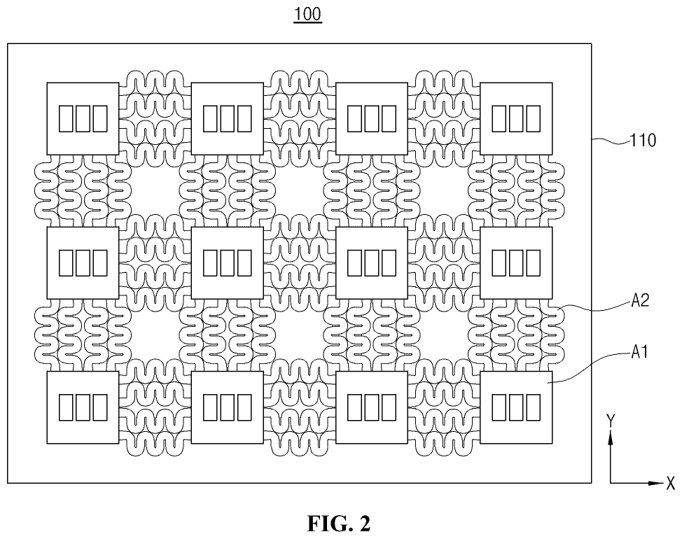

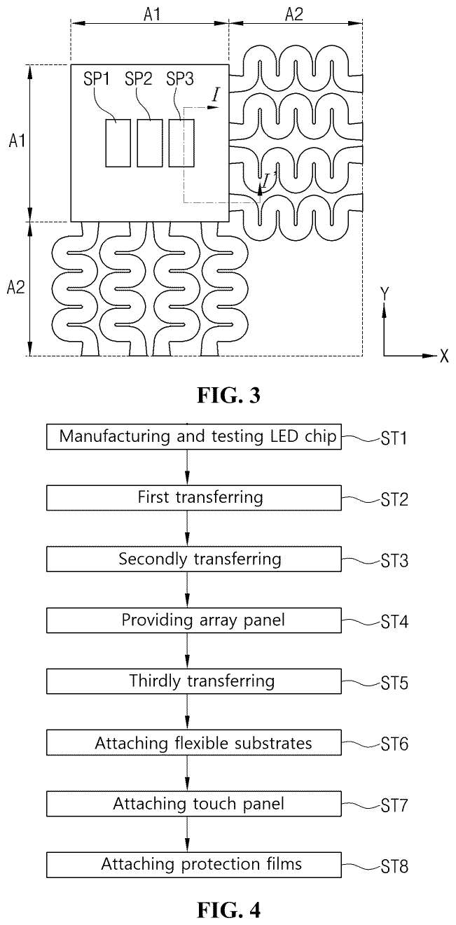

The planar configuration of the display panel of the stretchable display device will be described in detail with reference to FIG. 2 and FIG. 3.

FIG. 2 is a schematic plan view of a display panel of a stretchable display device according to an embodiment of the present disclosure, and FIG. 3 is a plan view schematically illustrating a part of a display panel of a stretchable display device according to an embodiment of the present disclosure.

In FIG. 2 and FIG. 3, the display panel 100 may be stretched in a first direction X and/or a second direction Y. The display panel 100 may include a base substrate 110, and a rigid portion A1 corresponding to a first area and a soft portion A2 corresponding to a second area may be provided on the base substrate 110. The rigid portion A1 may not be stretched, and the soft portion A2 may be stretched.

The rigid portion A1 may be provided in the form of an island, and a plurality of rigid portions A1 may be disposed to be spaced apart from each other along the first direction X and the second direction Y. For example, the rigid portion A1 may have a substantially rectangular shape. The rigid portions A1 may be arranged in a matrix form.

A pixel including a plurality of sub-pixels SP1, SP2, and SP3 may be provided in the rigid portion A1. For example, first, second, and third sub-pixels SP1, SP2, and SP3 may be provided in the rigid portion A1, and the first, second, and third sub-pixels SP1, SP2, and SP3 may be red, green, and blue sub-pixels, respectively.

Each of the plurality of sub-pixels SP1, SP2, and SP3 may include a light-emitting element, at least one thin film transistor, and at least one capacitor.

The soft portion A2 may be disposed between adjacent rigid portions A1 in each of the first direction X and the second direction Y. A stretchable line that is a connection line connecting the adjacent pixels may be provided in the soft portion A2. The stretchable line may include a plurality of voltage lines such as a gate line, a data line, a high potential line, a low potential line, an emission line, and a reference voltage line.

The stretchable line may have at least one curved part. For example, the stretchable line may have a wave structure and may include a plurality of wave shapes.

A manufacturing process of a stretchable display device including the display panel will be described with reference to FIG. 4.

FIG. 4 is a view schematically showing a manufacture procedure of a stretchable display device according to an embodiment of the present disclosure and will be described with reference to FIG. 1 together. Here, a configuration using a light-emitting diode chip as a light-emitting element will be described as an example.

As shown in FIG. 4, at a first step ST1, light-emitting diode (LED) chips may be manufactured and tested. Here, the LED chips may be manufactured on respective substrates for red, green, and blue colors. For example, the substrates may be a sapphire wafer.

Next, at a second step ST2, the LED chips may be first transferred on a first donor. In this case, red, green, and blue LED chips may be transferred on respective first donors, and a total of three first transfer processes may be performed. Accordingly, three first donors on which the red, green, and blue LED chips are respectively transferred may be prepared. For example, the first donor may be formed of polydimethylsiloxane (PDMS), and the first transfer may be performed using a laser beam.

Next, at a third step ST3, the LED chips transferred on the first donors may be secondly transferred on a second donor on which patterns corresponding to an array panel are formed. In this case, all the red, green, and blue LED chips may be transferred on the second donor. Since the red, green, and blue LED chips are separately on the second donor, a total of three second transfer processes may be performed. Accordingly, the single second donor on which the red, green, and blue LED chips are transferred together may be prepared. For example, the second donor may be a glass substrate provided with metal patterns and a UV film. The second transfer may be performed by attaching and then detaching the first donor and the second donor using a difference in adhesion. In addition, a process of irradiating UV on the second donor on which the LED chips are transferred may be further performed.

Next, at a fourth step ST4, an array panel may be provided. The array panel may have a configuration in which the light-emitting elements are omitted in the display panel 100 of FIG. 2. Here, the array panel may include first and second electrodes having protrusions and an adhesive layer between the first and second electrodes.

The fourth step ST4 may be performed before one of the first, second, and third steps ST1, ST2, and ST3.

Next, at a fifth step ST5, the red, green, and blue LED chips transferred on the second donor may be thirdly transferred on the array panel. For example, the third transfer may be performed by attaching the second donor and the array panel, curing the adhesive layer of the array panel to fix the red, green, and blue LED chips on the array panel, and detaching the second donor. Accordingly, the display panel 100 including the LED chips may be completed.

Next, at a sixth step ST6, the first flexible substrate 162 and the second flexible substrate 166 may be attached to the lower part and the upper part of the display panel 100, respectively.

Next, at a seventh step ST7, the touch panel 170 may be attached to the upper part of the display panel, specifically, the upper part of the second flexible substrate 166.

Next, at an eighth step ST8, the first protection film 182 may be attached to the lower part of the display panel 100, specifically, the lower part of the first flexible substrate 162, and the second protection film 184 may be attached to the upper part of the touch panel 170. In this case, the third flexible substrate 174 may be provided between the touch panel 170 and the second protection film 184.

As such, in the stretchable display device according to the embodiment of the present disclosure, the LED chips may be fixed and electrically connected by the first and second electrodes having the protrusions and the adhesive layer between the first and second electrodes, and this will be described in detail later.

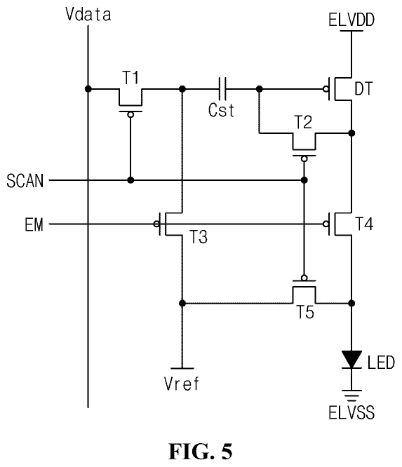

FIG. 5 is an equivalent circuit diagram for a sub-pixel of a stretchable display device according to an embodiment of the present disclosure.

In FIG. 5, one sub-pixel of the stretchable display device according to the embodiment of the present disclosure, that is, each of the first, second, and third sub-pixels SP1, SP2, and SP3 may include a driving transistor DT, first, second, third, fourth, and fifth transistors T1, T2, T3, T4, and T5, a storage capacitor Cst, and a light-emitting diode LED.

For example, the driving transistor DT and the first, second, third, fourth, and fifth transistors T1, T2, T3, T4, and T5 may be P-type transistors. However, embodiments of the present disclosure are not limited thereto. In other embodiments, the driving transistor DT and the first, second, third, fourth, and fifth transistors T1, T2, T3, T4, and T5 may be N-type transistors.

The driving transistor DT may be switched according to a voltage of a first capacitor electrode of the storage capacitor Cst and may be connected to a high potential voltage ELVDD. Specifically, a gate of the driving transistor DT may be connected to the first capacitor electrode of the storage capacitor Cst and a source of the second transistor T2. A source of the driving transistor DT may be connected to the high potential voltage ELVDD. A drain of the driving transistor DT may be connected to a drain of the second transistor T2 and a source of the fourth transistor T4.

The first transistor T1 may be switched according to a gate signal SCAN and may be connected to a data signal Vdata. Specifically, a gate of the first transistor T1 may be connected to the gate signal SCAN. A source of the first transistor T1 may be connected to the data signal Vdata. A drain of the first transistor T1 may be connected to a second capacitor electrode of the storage capacitor Cst and a source of the third transistor T3.

The second transistor T2 may be switched according to the gate signal SCAN and may be connected to the driving transistor DT. Specifically, a gate of the second transistor T2 may be connected to the scan signal SCAN. The source of the second transistor T2 may be connected to the first capacitor electrode of the storage capacitor Cst and the gate of the driving transistor DT. The drain of the second transistor T2 may be connected to the source of the driving transistor DT and the source of the fourth transistor T4.

The third transistor T3 may be switched according to an emission signal EM and may be connected to a reference voltage Vref. A gate of the third transistor T3 may be connected to the emission signal EM. The source of the third transistor T3 may be connected to the second capacitor electrode of the storage capacitor Cst and the drain of the first transistor T1. A drain of the third transistor T3 may be connected to the reference voltage Vref and a source of the fifth transistor T5.

The fourth transistor T4 may be switched according to the emission signal EM and may be connected to the driving transistor DT and the light-emitting diode LED. Specifically, a gate of the fourth transistor T4 may be connected to the emission signal EM. The source of the fourth transistor T4 may be connected to the drain of the driving transistor DT and the drain of the second transistor T2. A drain of the fourth transistor T4 may be connected to a drain of the fifth transistor T5 and a first electrode of the light-emitting diode LED.

The fifth transistor T5 may be switched according to the gate signal SCAN and may be connected to the reference voltage Vref and the fourth transistor T4. Specifically, a gate of the fifth transistor T5 may be connected to the scan signal SCAN. The source of the fifth transistor T5 may be connected to the reference voltage Vref and the drain of the third transistor T3. The drain of the fifth transistor T5 may be connected to the drain of the fourth transistor T4 and the first electrode of the light-emitting diode LED.

The storage capacitor Cst may store the data signal Vdata and a threshold voltage Vth of the driving transistor DT. The first capacitor electrode of the storage capacitor Cst may be connected to the gate of the driving transistor DT and the source of the second transistor T2. The second capacitor electrode of the storage capacitor Cst may be connected to the drain of the first transistor T1 and the source of the third transistor T3.

The light-emitting diode LED may be connected between the fourth and fifth transistors T4 and T5 and a low potential voltage ELVSS and may emit light with luminance proportional to a current of the driving transistor DT. The first electrode of the light-emitting diode LED, which is an anode, may be connected to the drain of the fourth transistor T4 and the drain of the fifth transistor T5. The second electrode of the light-emitting diode LED, which is a cathode, may be connected to the low potential voltage ELVSS.

In the embodiment of the present disclosure of FIG. 5, as an example, each sub-pixel has a 6T1C structure including six transistors and one capacitor, but in other embodiments, each sub-pixel may have one of 2T1C, 4T1C, 5T1C, 3T2C, 4T2C, 5T2C, 6T2C, 7T1C, 7T2C, 8T1C, and 8T2C structures.

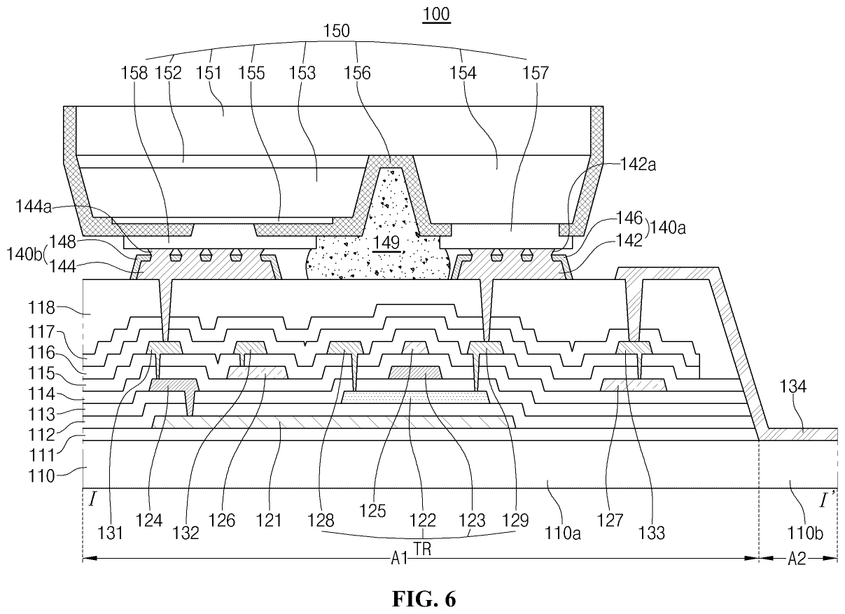

A cross-sectional structure of a stretchable display device according to an embodiment of the present disclosure will be described in detail with reference to FIG. 6.

FIG. 6 is a schematic cross-sectional view of a stretchable display device according to an embodiment of the present disclosure. FIG. 6 shows a cross-section corresponding to line I-I′ of FIG. 3 and will be described with reference to FIGS. 1 to 5 together.

In FIG. 6, the stretchable display device 100 according to the embodiment of the present disclosure may include a base substrate 110 provided with a rigid portion A1 and a soft portion A2.

The base substrate 110 may include a first base portion 10a and a second base portion 110b. The first base portion 110a may be disposed to correspond to the rigid portion A1, and the second base portion 110b may be disposed to correspond to the soft portion A2.

The first base portion 110a may be provided in a plate shape in a display area and may serve to support and protect components of the plurality of sub-pixels SP1, SP2, and SP3. The first base portion 110a may be plural, and the plurality of first base portions 110a may be spaced apart from each other in the first direction X and the second direction Y.

The second base portion 110b may be provided between adjacent first base portions 110a. The second base portion 110b may include at least one curved part and may serve to support and protect a stretchable line 134.

The first and second base portions 110a and 110b may be connected to each other and may be provided as one-body.

The base substrate 110 may be formed of a rigid material having lower flexibility than the soft material of the first and second flexible substrates 162 and 166. For example, the base substrate 110 may be formed of a polyimide (PI) resin or epoxy resin.

The base substrate 110 may have relatively high elastic modulus, and the elastic modulus of the base substrate 110 may be higher than the elastic modulus of the first and second flexible substrates 162 and 166. For example, the elastic modulus of the base substrate 110 may be more than 1,000 times higher than the elastic modulus of the first and second flexible substrates 162 and 166, but embodiments of the present disclosure are not limited thereto.

A first buffer layer 111 may be provided on the base substrate 110 as a first insulation layer. The first buffer layer 111 may block permeation of moisture or oxygen from the outside to protect the components of the plurality of sub-pixels SP1, SP2, and SP3.

The first buffer layer 111 may be formed as a single layer or multiple layers of an inorganic insulating material. The inorganic insulating material of the first buffer layer 111 may include silicon nitride (SiNx), silicon oxide (SiOx), or silicon oxynitride (SiON).

In order to prevent or at least reduce damage of the first buffer layer 111 such as cracks due to stretching, the first buffer layer 111 may be removed in the soft portion A2 to substantially correspond to the rigid portion A1, so that the first buffer layer 111 may be provided over the first base portion 110a of the base substrate 110 and may not be provided over the second base portion 110b.

In other embodiments, the first buffer layer 111 may be omitted.

A light shielding layer 121 may be provided on the first buffer layer 111. The light shielding layer 121 may be formed of a conductive material such as metal. For example, the light shielding layer 121 may be formed of at least one of aluminum (Al), copper (Cu), molybdenum (Mo), titanium (Ti), chromium (Cr), nickel (Ni), tungsten (W), or an alloy thereof. The light shielding layer 121 may have a single-layered structure or a multiple-layered structure.

A second buffer layer 112 may be provided on the light shielding layer 121 as a second insulation layer. The second buffer layer 112 may be formed as a single layer or multiple layers of an inorganic insulating material. The inorganic insulating material of the second buffer layer 112 may include silicon nitride (SiNx), silicon oxide (SiOx), or silicon oxynitride (SiON).

In order to prevent or at least reduce damage of the second buffer layer 112 such as cracks due to stretching, the second buffer layer 112 may be removed in the soft portion A2 to substantially correspond to the rigid portion A1. The second buffer layer 112 may be provided over the first base portion 110a of the base substrate 110 and may not be provided over the second base portion 110b.

A semiconductor layer 122 may be provided on the second buffer layer 112. The semiconductor layer 122 may overlap the light shielding layer 121, and the light shielding layer 121 may block light incident on the semiconductor layer 122 and prevent the semiconductor layer 122 from deteriorating due to the light.

The semiconductor layer 122 may include a channel region at its central part and source and drain regions at both sides of the channel region.

The semiconductor layer 122 may be formed of an oxide semiconductor material. Alternatively, the semiconductor layer 122 may be formed of polycrystalline silicon, and in this case, both ends of the semiconductor layer 122 may be doped with impurities.

A gate insulation layer 113 may be provided on the semiconductor layer 122 as a third insulation layer. The gate insulation layer 113 may be formed as a single layer or multiple layers of an inorganic insulating material. The inorganic insulating material of the gate insulation layer 113 may include silicon nitride (SiNx), silicon oxide (SiOx), or silicon oxynitride (SiON).

In order to prevent or at least reduce damage of the gate insulation layer 113 such as cracks due to stretching, the gate insulation layer 113 may be removed in the soft portion A2 to substantially correspond to the rigid portion A1. The gate insulation layer 113 may be provided over the first base portion 110a of the base substrate 110 and may not be provided over the second base portion 110b.

A gate electrode 123 and a first connection electrode 124 may be provided on the gate insulation layer 113.

The gate electrode 123 may overlap the semiconductor layer 122 and may be disposed to correspond to the central part of the semiconductor layer 122. Accordingly, the gate electrode 123 may also overlap the light shielding layer 121.

The first connection electrode 124 may be spaced apart from the semiconductor layer 122 and may overlap the light shielding layer 121. The first connection electrode 124 may be in contact with the light shielding layer 124 through a contact hole provided in the second buffer layer 112 and the gate insulation layer 113.

The gate electrode 123 and the first connection electrode 124 may be formed of a conductive material such as metal. For example, the gate electrode 123 and the first connection electrode 124 may be formed of at least one of aluminum (Al), copper (Cu), molybdenum (Mo), titanium (Ti), chromium (Cr), nickel (Ni), tungsten (W), or an alloy thereof. The gate electrode 123 and the first connection electrode 124 may have a single-layered structure or a multiple-layered structure.

A first interlayer insulation layer 114 may be provided on the gate electrode 123 and the first connection electrode 124 as a fourth insulation layer. The first interlayer insulation layer 114 may be formed as a single layer or multiple layers of an inorganic insulating material. The inorganic insulating material of the first interlayer insulation layer 114 may include silicon nitride (SiNx), silicon oxide (SiOx), or silicon oxynitride (SiON).

In order to prevent or at least reduce damage of the first interlayer insulation layer 114 such as cracks due to stretching, the first interlayer insulation layer 114 may be removed in the soft portion A2 to substantially correspond to the rigid portion A1. The first interlayer insulation layer 114 may be provided over the first base portion 110a of the base substrate 110 and may not be provided over the second base portion 110b.

An auxiliary electrode 125, an auxiliary line 126, and a pad electrode 127 may be provided on the first interlayer insulation layer 114. The auxiliary electrode 125 may overlap gate electrode 123, the semiconductor layer 122, and the light shielding layer 121. The auxiliary line 126 may overlap the light shielding layer 121 and may be spaced apart from the gate electrode 123, the semiconductor layer 122, and the first connection electrode 124. The pad electrode 127 may be spaced apart from the light shielding layer 121 and may be disposed close to an edge of the rigid portion A1 adjacent to the soft portion A2.

The auxiliary electrode 125, the auxiliary line 126, and the pad electrode 127 may be formed of a conductive material such as metal. For example, the auxiliary electrode 125, the auxiliary line 126, and the pad electrode 127 may be formed of at least one of aluminum (Al), copper (Cu), molybdenum (Mo), titanium (Ti), chromium (Cr), nickel (Ni), tungsten (W), or an alloy thereof. The auxiliary electrode 125, the auxiliary line 126, and the pad electrode 127 may have a single-layered structure or a multiple-layered structure.

A second interlayer insulation layer 115 may be provided on the auxiliary electrode 125, the auxiliary line 126, and the pad electrode 127 as a fifth insulation layer. The second interlayer insulation layer 115 may be formed as a single layer or multiple layers of an inorganic insulating material. The inorganic insulating material of the second interlayer insulation layer 115 may include silicon nitride (SiNx), silicon oxide (SiOx), or silicon oxynitride (SiON).

In order to prevent or at least reduce damage of the second interlayer insulation layer 115 such as cracks due to stretching, the second interlayer insulation layer 115 may be removed in the soft portion A2 to substantially correspond to the rigid portion A1. The second interlayer insulation layer 115 may be provided over the first base portion 110a of the base substrate 110 and may not be provided over the second base portion 110b.

A source electrode 128, a drain electrode 129, a second connection electrode 131, and a power line 132 may be provided on the second interlayer insulation layer 115.

The source electrode 128 and the drain electrode 129 may be spaced apart from each other with the gate electrode 123 positioned therebetween and may be in contact with both ends of the semiconductor layer 122 through contact holes provided in the first and second interlayer insulation layers 114 and 115 and the gate insulation layer 113. The gate electrode 123 and the auxiliary electrode 125 may be disposed between the source electrode 128 and the drain electrode

The semiconductor layer 122, the gate electrode 123, the source electrode 128, and the drain electrode 129 may constitute a thin film transistor TR.

The second connection electrode 131 may be spaced apart from the thin film transistor TR. The second connection electrode 131 may overlap the first connection electrode 124 and may be in contact with the first connection electrode 124 through a contact hole provided in the first and second interlayer insulation layers 114 and 115. In addition, the second connection electrode 131 may overlap the light shielding layer 121.

The power line 132 may be spaced apart from the thin film transistor TR. The power line 132 may overlap the auxiliary line 126 and may be in contact with the auxiliary line 126 through a contact hole formed in the second interlayer insulation layer 115.

For example, the power line 132 may be a line supplying the low potential voltage ELVSS. In this case, the power line 132 or the auxiliary line 126 may be connected to the light shielding layer 121. That is, the light shielding layer 121 may be supplied with the low potential voltage ELVSS.

The source electrode 128, the drain electrode 129, the second connection electrode 131, and the power line 132 may be formed of a conductive material such as metal. For example, the source electrode 128, the drain electrode 129, the second connection electrode 131, and the power line 132 may be formed of at least one of aluminum (Al), copper (Cu), molybdenum (Mo), titanium (Ti), chromium (Cr), nickel (Ni), tungsten (W), or an alloy thereof. The source electrode 128, the drain electrode 129, the second connection electrode 131, and the power line 132 may have a single-layered structure or a multiple-layered structure.

A third interlayer insulation layer 116 may be provided on the source electrode 128, the drain electrode 129, the second connection electrode 131, and the power line 132 as a sixth insulation layer. The third interlayer insulation layer 116 may be formed as a single layer or multiple layers of an inorganic insulating material. The inorganic insulating material of the third interlayer insulation layer 116 may include silicon nitride (SiNx), silicon oxide (SiOx), or silicon oxynitride (SiON).

In order to prevent or at least reduce damage of the third interlayer insulation layer 116 such as cracks due to stretching, the third interlayer insulation layer 116 may be removed in the soft portion A2 to substantially correspond to the rigid portion A1. The third interlayer insulation layer 116 may be provided over the first base portion 110a of the base substrate 110 and may not be provided over the second base portion 110b.

An auxiliary pad 133 may be provided on the third interlayer insulation layer 116. The auxiliary pad 133 may overlap the pad electrode 127 and may be in contact with the pad electrode 127 through a contact hole provided in the second and third interlayer insulation layers 115 and 116.

The auxiliary pad 133 may be formed of a conductive material such as metal. For example, the auxiliary pad 133 may be formed of at least one of aluminum (Al), copper (Cu), molybdenum (Mo), titanium (Ti), chromium (Cr), nickel (Ni), tungsten (W), or an alloy thereof. The auxiliary pad 133 may have a single-layered structure or a multiple-layered structure.

A passivation layer 117 may be provided on the auxiliary pad 133. The passivation layer 117 may be formed as a single layer or multiple layers of an inorganic insulating material. The inorganic insulating material of the passivation layer 117 may include silicon nitride (SiNx), silicon oxide (SiOx), or silicon oxynitride (SiON).

In order to prevent or at least reduce damage of the passivation layer 117 such as cracks due to stretching, the passivation layer 117 may be removed in the soft portion A2 to substantially correspond to the rigid portion A1. The passivation layer 117 may be provided over the first base portion 110a of the base substrate 110 and may not be provided over the second base portion 110b.

In this case, edges of the passivation layer 117 and the third interlayer insulation layer 116 of the rigid portion A1 adjacent to the soft portion A2 may be partially removed, thereby exposing a top surface of the second interlayer insulation layer 115.

The passivation layer 117 may be omitted.

A planarization layer 118 may be provided on the passivation layer 117. The planarization layer 118 may eliminate a step difference due to the layers thereunder and may have a substantially flat top surface. The planarization layer 118 may be formed of an organic insulating material such as photosensitive acrylic polymer (photo acryl).

The planarization layer 118 may be provided in the rigid portion A1 and may not be provided in the soft portion A2. Accordingly, the planarization layer 118 may be provided over the first base portion 110a of the base substrate 110 and may not be provided over the second base portion 110b.

In the rigid portion A1, the planarization layer 118 may be in contact with side surfaces of the third interlayer insulation layer 116 and the passivation layer 117 and be in contact with the exposed top surface of the second interlayer insulation layer 115.

The stretchable line 134 may be provided on the planarization layer 118. An end of the stretchable line 134 may be disposed on the planarization layer 118 of the rigid portion A1. The end of the stretchable line 134 may overlap the auxiliary pad 133 and may be in contact with the auxiliary pad 133 through a contact hole provided in the planarization layer 118 and the passivation layer 117. The end of the stretchable line 134 may overlap the pad electrode 127.

The stretchable line 134 may extend into and be provided in the soft portion A2. The stretchable line 134 may be in contact with a top surface of the second base portion 110b in the soft portion A2. The stretchable line 134 may be in contact with side surfaces of the first buffer layer 111, the second buffer layer 112, the gate insulation layer 113, the first interlayer insulation layer 114, the second interlayer insulation layer 115, and the planarization layer 118.

The stretchable line 134 may be formed of a conductive material such as metal. For example, the stretchable line 134 may be formed of at least one of aluminum (Al), copper (Cu), molybdenum (Mo), titanium (Ti), chromium (Cr), nickel (Ni), tungsten (W), or an alloy thereof. The stretchable line 134 may have a single-layered structure or a multiple-layered structure.

In addition, a first electrode 140a and a second electrode 140b may be provided on the planarization layer 118. The first electrode 140a may overlap the drain electrode 129 and may be in contact with the drain electrode 129 through a contact hole provided in the planarization layer 118, the passivation layer 117, and the third interlayer insulation layer 116. The second electrode 140b may overlap the second connection electrode 131 and may be in contact with the second connection electrode 131 through a contact hole provided in the planarization layer 118, the passivation layer 117, and the third interlayer insulation layer 116.

The first electrode 140a and the second electrode 140b may have a double-layered structure. Here, a thickness of the first electrode 140a and the second electrode 140b may be equal to or greater than a thickness of the stretchable line 134.

Specifically, the first electrode 140a may include a first lower electrode 142 and a first upper electrode 146 stacked, and the second electrode 140b may include a second lower electrode 144 and a second upper electrode 148 stacked. The first upper electrode 146 may cover top and side surfaces of the first lower electrode 142, and the second upper electrode 148 may cover top and side surfaces of the second lower electrode 144.

Here, a thickness of the first and second lower electrodes 142 and 144 may be greater than a thickness of the first and second upper electrodes 146 and 148. In addition, the thickness of the first and second lower electrodes 142 and 144 may be equal to or greater than the thickness of the stretchable line 134.

The first lower electrode 142 may include a plurality of first protrusions 142a spaced apart from each other with a predetermined space, and the plurality of first protrusions 142a may protrude upward through respective holes provided in the first upper electrode 146. The second lower electrode 144 may include a plurality of second protrusions 144a spaced apart from each other with a predetermined space, and the plurality of second protrusions 144a may protrude upward through respective holes provided in the second upper electrode 148.

In this case, a thickness of the first and second protrusions 142a and 144a may be greater than the thickness of the first and second upper electrodes 146 and 148, so that the first and second protrusions 142a and 144a may protrude above the first and second upper electrodes 146 and 148 according to one embodiment.

The first protrusions 142a and the second protrusions 144a may be in contact with a light-emitting element 150. In this case, a width of a top surface of each of the first and second protrusions 142a and 144a contacting the light-emitting element 150 may be equal to or greater than a width of the hole corresponding thereto. However, embodiments of the present disclosure are not limited thereto.

The first and second electrodes 140a and 140b may be formed of a different material from the stretchable line 134. In this case, the first lower electrode 142 and the second lower electrode 144 may be formed of the same material, the first upper electrode 146 and the second upper electrode 148 may be formed of the same material, and the first lower electrode 142 and the second lower electrode 144 may be formed of a different material from the first upper electrode 146 and the second upper electrode 148.

For example, the first lower electrode 142 and the second lower electrode 144 may be formed as a single layer or multiple layers including silver (Ag), and the first upper electrode 146 and the second upper electrode 148 may be formed of a transparent conductive material such as indium tin oxide (ITO) or indium zinc oxide (IZO). However, embodiments of the present disclosure are not limited thereto.

In addition, an adhesive layer 149 may be provided on the planarization layer 118. The adhesive layer 149 may be disposed between the first electrode 140a and the second electrode 140b. For example, the adhesive layer 149 may be formed of an acryl-based, silicon-based, or urethane-based organic material. A thickness of the adhesive layer 149 may be greater than the thickness of the first and second electrodes 140a and 140b.

The light-emitting element 150 may be provided on the first electrode 140a, the second electrodes 140b, and the adhesive layer 149. The light-emitting element 150 may be provided in the form of a micro light-emitting diode chip (micro-LED chip or uLED chip) including a p-type layer 151, an active layer 152, an n-type layer 153, a p-electrode 157, and an n-electrode 158. In addition, the light-emitting element 150 may further include a first ohmic layer 154, a second ohmic layer 155, and a protection layer 156.

Specifically, the first ohmic layer 154 and the p-electrode 157 may be sequentially provided on one side of a bottom surface of the p-type layer 151, and the active layer 152, the n-type layer 153, the second ohmic layer 155, and the n-electrode 158 may be spaced apart from the first ohmic layer 154 and sequentially provided on another side of the bottom surface of the p-type layer 151.

Here, the protection layer 156 may be provided between the first ohmic layer 154 and the p-electrode 157 and between the second ohmic layer 155 and the n-electrode 158. The p-electrode 157 may be in contact with the first ohmic layer 154 through a contact hole formed in the protection layer 156, and the n-electrode 158 may be in contact with the second ohmic layer 155 through a contact hole formed in the protection layer 156. The protection layer 156 may cover and be in contact with a side surface of the first ohmic layer 154 and may cover and be in contact with side surfaces of the active layer 152, the n-type layer 153, and the second ohmic layer 155. In addition, the protection layer 156 may be in contact with the bottom surface of the p-type layer 151 between the first ohmic layer 154 and the active layer 152.

The p-electrode 157 of the light-emitting element 150 may be in contact with the first protrusions 142a of the first electrode 140a, and the n-electrode 158 may be in contact with the second protrusions 144a of the second electrode 140b. In addition, the p-electrode 157 may further be in contact with the first upper electrode 146 together with the first protrusions 142a of the first electrode 140a, and the n-electrode 158 may further be in contact with the second upper electrode 148 together with the second protrusions 144a of the second electrode 140b. Accordingly, the p-electrode 157 of the light-emitting layer 150 may be connected to the drain electrode 129 of the thin film transistor TR through the first electrode 140a, and the n-electrode 158 may be connected to the low potential voltage ELVSS through the second electrode 140b.

The light-emitting element 150 may have a flip-chip structure in which the p-electrode 157 and the n-electrode 158 are provided on the same side (for example, a side facing the base substrate 110) and light is emitted through a side opposite to the side provided with the p-electrode 157 and the n-electrode 158 (for example, a top surface of the p-type layer 151). However, embodiments of the present disclosure are not limited thereto. Further, the light-emitting element 150 of FIG. 6 has been described as a structure of a general red light-emitting diode in which the first ohmic layer 154 and the p-type layer 151 are sequentially placed on the p-electrode 157 and the second ohmic layer 155, the n-type layer 153, the active layer 152, and the p-type layer 151 are sequentially placed on the n-electrode 158. Alternatively, the light-emitting element 150 of FIG. 6 may be a general green or blue light-emitting diode in which the first ohmic layer, the p-type layer, the active layer, and n-type layer are sequentially placed on the p-electrode and the second ohmic layer and the n-type layer are sequentially placed on the n-electrode 158, and in this case, the arrangement and connection of the element may be changed in order to match the first and second electrodes 140a and 140b.

At this time, the light-emitting element 150 may have a concave portion between the p-electrode 157 and the n-electrode 158. The adhesive layer 149 may correspond to the concave portion of the light-emitting element 150 and may be in contact with the protection layer 156 in the concave portion.

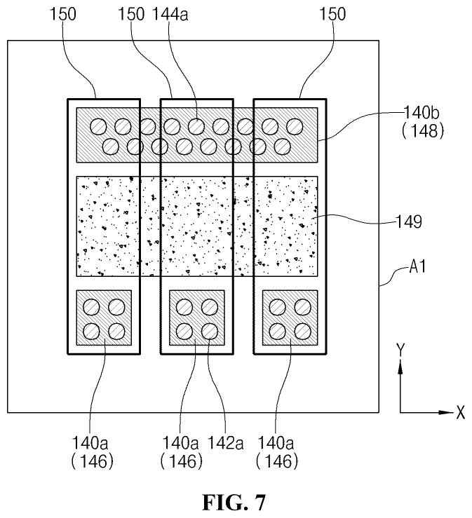

FIG. 7 is a schematic plan view of a pixel structure of a stretchable display device according to an embodiment of the present disclosure. FIG. 7 shows an arrangement of the first and second electrodes, the adhesive layer, and the light-emitting elements and will be described with reference to FIG. 6 together.

In FIG. 7, the plurality of first electrodes 140a and one second electrode 140b may be provided in one rigid portion A1. For example, three first electrodes 140a may be disposed to be spaced apart from each other in the first direction X, and the second electrode 140b may be disposed to be spaced apart from the first electrodes 140a in the second direction Y.

Each first electrode 140a may have the plurality of first protrusions 142a, and the plurality of first protrusions 142a may be exposed through the plurality of holes of the first upper electrode 146, respectively. In addition, the second electrode 140b may have the plurality of second protrusions 144a, and the plurality of second protrusions 144a may be exposed through the plurality of holes of the second upper electrode 148, respectively.

The adhesive layer 149 may be provided between the first electrode 140a and the second electrode 140b, and each light-emitting element 150 may be provided to overlap the first electrode 140a, the second electrode 140b, and the adhesive layer 149.

In this case, the p-electrodes 157 of the three light-emitting elements 150 may overlap and be in contact with the three first electrodes 140a, respectively, and the n-electrodes 158 of the three light-emitting elements 150 may overlap and be in contact with the second electrode 140b.

As such, in the stretchable display device according to the embodiment of the present disclosure, the first electrode 140a and the second electrode 140b may be formed to have the first protrusions 142a and the second protrusions 144a, respectively, the first and second protrusions 142a and 144a may be in contact with and connected to the p-electrode 157 and the n-electrode 158 of the light-emitting element 150, respectively, and the light-emitting element 150 may be fixed by the adhesive layer 149 between the first electrode 140a and the second electrode 140b.

Accordingly, since the p-electrode 157 and the n-electrode 158 of the light-emitting element 150 are directly connected to the first electrode 140a and the second electrode 140b, respectively, the contact resistance between two electrodes may be relatively small compared to the case that the anisotropic conductive film is used in the related art, thereby improving the electrical properties of the light-emitting element 150. In addition, the anisotropic conductive film may be omitted, thereby reducing the manufacturing costs.

In this case, the first electrode 140a and the second electrode 140b may each have the double-layered structure including the lower electrode 142 and 144 and the upper electrode 146 and 148, so that the first upper electrode 146 and the second upper electrode 148 can protect the first lower electrode 142 having the first protrusions 142a and the second lower electrode 144 having the second protrusions 144a to thereby prevent defects and can assist the contact with the light-emitting element 150.

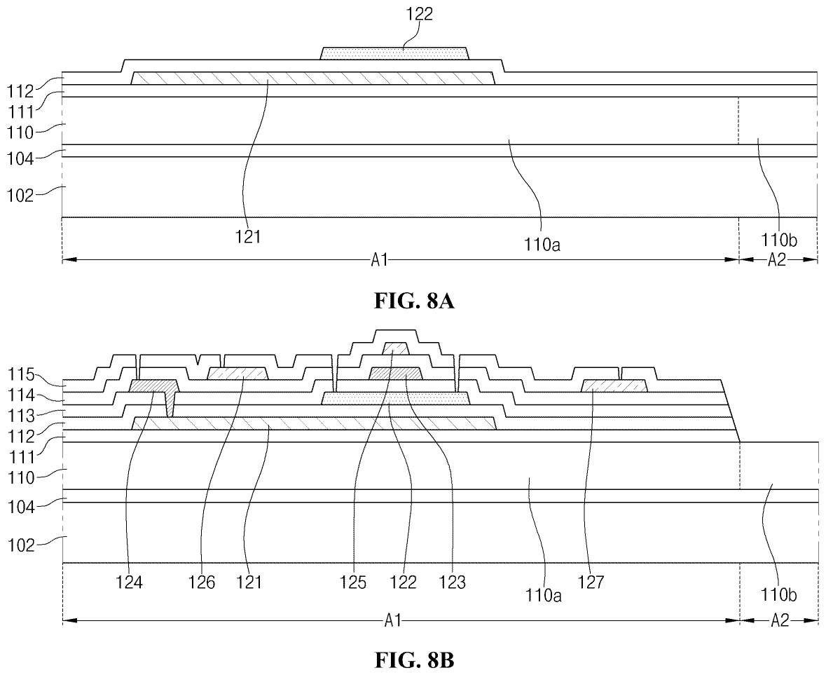

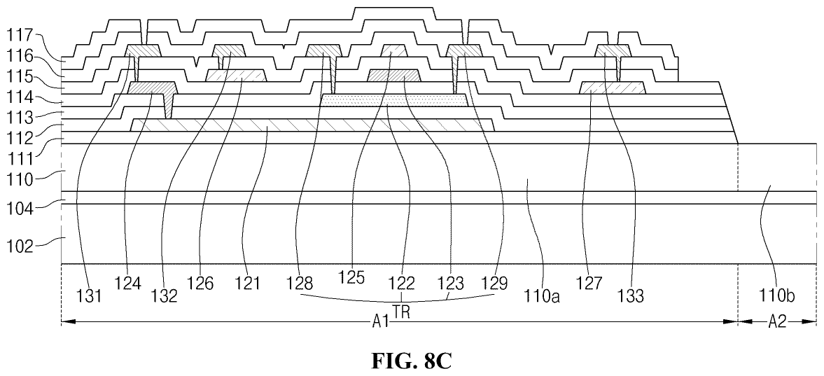

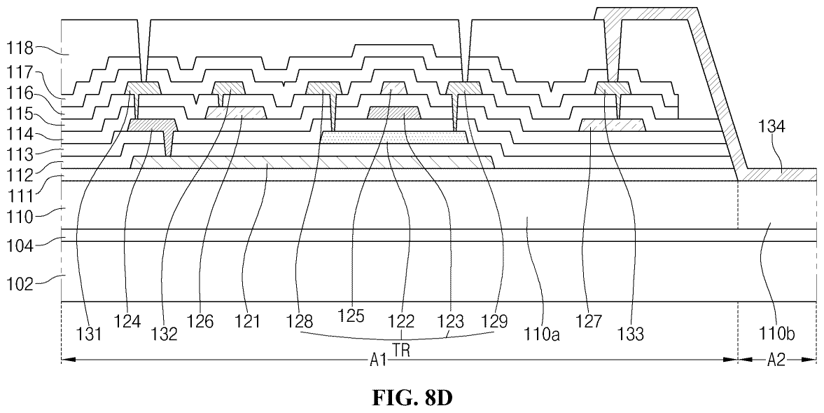

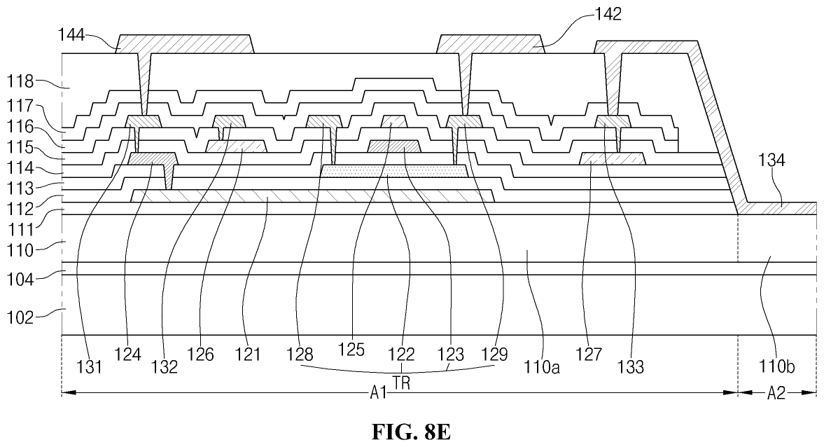

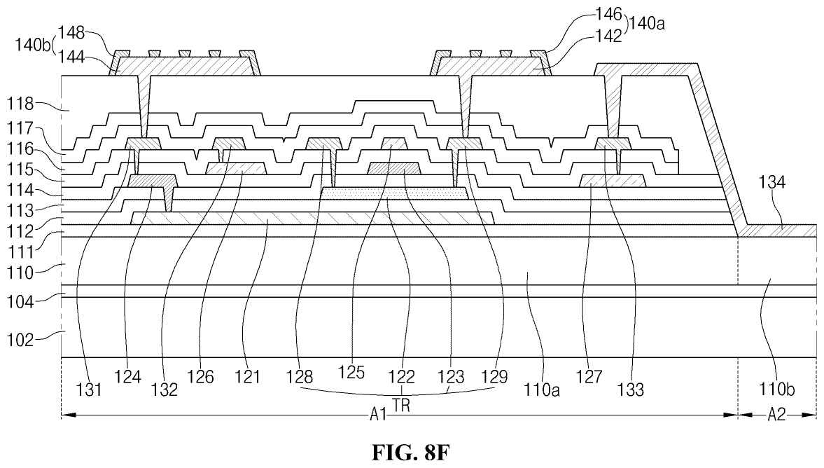

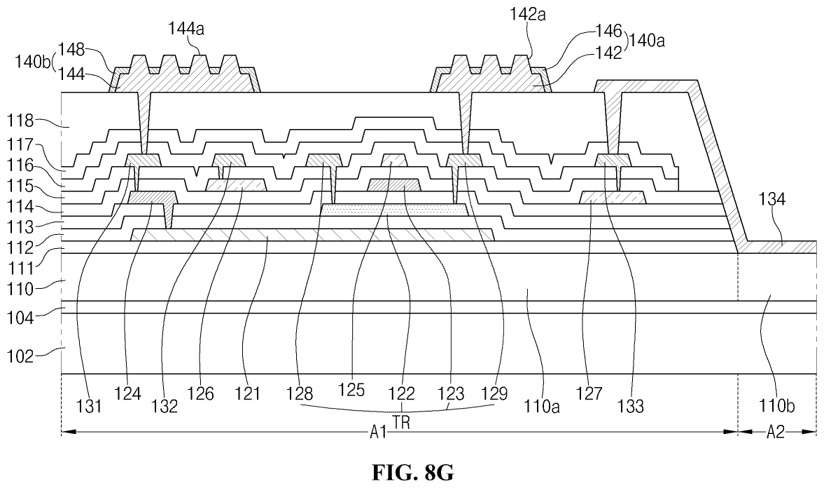

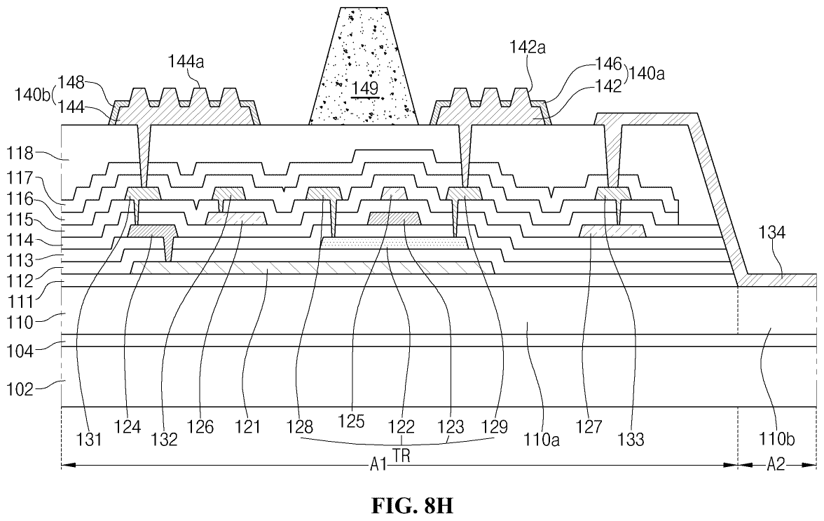

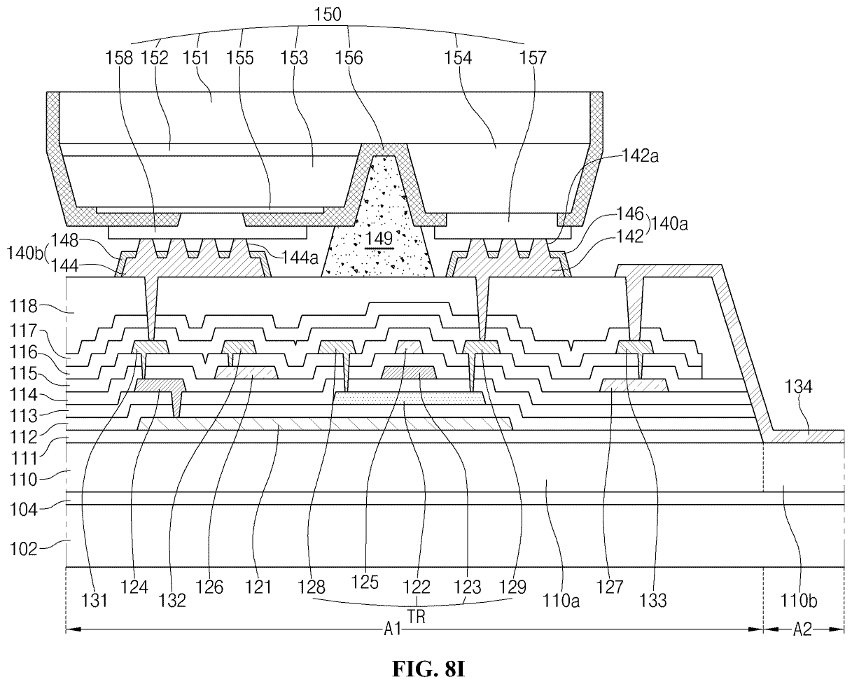

A method of manufacturing a stretchable display device according to an embodiment of the present disclosure will be described with reference to FIGS. 8A to 8I.

FIGS. 8A to 8I are schematic cross-sectional views of a display panel in steps of manufacturing a stretchable display device according to a first embodiment of the present disclosure. FIGS. 8A to 8I show cross-sections corresponding to line I-I′ of FIG. 3, and will be described with reference to FIG. 6 together.

In FIG. 8A, a sacrificial layer 104 may be formed on a carrier substrate 102 provided with the rigid portion A1 and the soft portion A2. Here, the sacrificial layer 104 may be an inorganic layer and may be formed through a deposition process. For example, the sacrificial layer 104 may be formed by stacking amorphous silicon (a-Si) and silicon nitride (SiNx). In addition, the carrier substrate 102 may be formed of glass.

Then, the base substrate 110 may be formed of an insulating material and on the sacrificial layer 104. The base substrate 110 may be formed over substantially an entire surface of the carrier substrate 102 and may include the first base portion 110a corresponding to the rigid portion A1 and the second base portion 110b corresponding to the soft portion A2.

For example, the base substrate 110 may be formed by applying polyimide (PI) resin or epoxy resin and then curing it.

Then, the first buffer layer 111 may be formed on the base substrate 110 by depositing an inorganic insulating material over substantially the entire surface of the carrier substrate 102, and the light shielding layer 121 may be formed in the rigid portion A1 by depositing a conductive material on the first buffer layer 111 and then patterning it through a photolithography process.

Next, the second buffer layer 112 may be formed on the light shield layer 121 and the first buffer layer 111 by depositing an inorganic insulating material over substantially the entire surface of the carrier substrate 102, and the semiconductor layer 122 may be formed in the rigid portion A1 by depositing a semiconductor material on the second buffer layer 112 and then patterning it through a photolithography process. The semiconductor layer 122 may overlap the light shielding layer 121.

Next, in FIG. 8B, the gate insulation layer 113 may be formed on the semiconductor layer 122 and the second buffer layer 112 by depositing an inorganic insulating material over substantially the entire surface of the carrier substrate 102, and the gate insulation layer 113 and the second buffer layer 112 may be selectively removed through a photolithography process to thereby form the contact hole exposing the light shielding layer 121.

Then, the gate electrode 123 and the first connection electrode 124 may be formed in the rigid portion A1 by depositing a conductive material on the gate insulation layer 113 and then patterning it through a photolithography process. The gate electrode 123 may overlap the semiconductor layer 122, and the first connection electrode 124 may be in contact with the light shielding layer 121 through the contact hole formed in the gate insulation layer 113 and the second buffer layer 112.

Next, the first interlayer insulation layer 114 may be formed on the gate electrode 123, the first connection electrode 124, and the gate insulation layer 113 by depositing an inorganic insulating material over substantially the entire surface of the carrier substrate 102, and the auxiliary electrode 125, the auxiliary line 126, and the pad electrode 127 may be formed in the rigid portion A1 by depositing a conductive material on the first interlayer insulation layer 114 and then patterning it through a photolithography process. The auxiliary electrode 125 may overlap the gate electrode 123, the auxiliary line 126 may overlap the light shielding layer 121 between the gate electrode 123 and the first connection electrode 124, and the pad electrode 127 may be disposed between the light shielding layer 121 and the soft portion A2.

Then, the second interlayer insulation layer 115 may be formed on the auxiliary electrode 125, the auxiliary line 126, the pad electrode 127, and the first interlayer insulation layer 114 by depositing an inorganic insulating material over substantially the entire surface of the carrier substrate 102 and then may be patterned through a photolithography process to thereby form the contact holes exposing the auxiliary line 126 and the pad electrode 127. In this case, the first interlayer insulation layer 114 and/or the gate insulation layer 113 under the second interlayer insulation layer 115 may also be patterned, thereby forming the contact hole exposing the first connection electrode 124 and the contact holes exposing the semiconductor layer 122.

Meanwhile, in the soft portion A2, the second interlayer insulation layer 115 may be removed together with the layers thereunder, that is, the first buffer layer 111, the second buffer layer 112, the gate insulation layer 113, and the first interlayer insulation layer 114, thereby exposing the top surface of the second base portion 110b of the soft portion A2.

Next, in FIG. 8C, the source electrode 128, the drain electrode 129, the second connection electrode 131, and the power line 132 may be formed in the rigid portion A1 by depositing a conductive material on the second interlayer insulation layer 115 and then patterning it through a photolithography process.

The source electrode 128 and the drain electrode 129 may be spaced apart from each other with the gate electrode 123 positioned therebetween. The source electrode 128 and the drain electrode 129 may overlap the semiconductor layer 122 and may be in contact with both ends of the semiconductor layer 122 through the contact holes provided in the first and second interlayer insulation layers 114 and 115 and the gate insulation layer 113. The semiconductor layer 122, the gate electrode 123, the source electrode 128, and the drain electrode 129 may constitute the thin film transistor TR.

The second connection electrode 131 may overlap the first connection electrode 124 and may be in contact with the first connection electrode 124 through the contact hole provided in the first and second interlayer insulation layers 114 and 115.

The power line 132 may overlap the auxiliary line 126 and may be in contact with the auxiliary line 126 through the contact hole formed in the second interlayer insulation layer 115.

Then, the third interlayer insulation layer 116 may be formed on the source electrode 128, the drain electrode 129, the second connection electrode 131, the power line 132, and the second interlayer insulation layer 115 by depositing an inorganic insulating material over substantially the entire surface of the carrier substrate 102 and then may be patterned through a photolithography process to thereby form the contact hole exposing the pad electrode 127. The auxiliary pad 133 may be formed in the rigid portion A1 by depositing a conductive material on the third interlayer insulation layer 116 and then patterning it through a photolithography process. The auxiliary pad 133 may overlap the pad electrode 127 and may be in contact with the pad electrode 127 through the contact hole formed in the second interlayer insulation layer 115 and the third interlayer insulation layer 116.

Next, the passivation layer 117 may be formed on the auxiliary pad 133 and the third interlayer insulation layer 116 by depositing an inorganic insulating material over substantially the entire surface of the carrier substrate 102 and then may be patterned through a photolithography process to thereby form the contact hole exposing the auxiliary pad 133. In this case, the third interlayer insulation layer 116 under the passivation layer 117 may also be patterned, thereby forming the contact hole exposing the drain electrode 129 and the contact hole exposing the second connection electrode 131.

Meanwhile, in the soft portion A2, the passivation layer 117 may be removed together with the third interlayer insulation layer 116 thereunder, thereby exposing the top surface of the second base portion 110b of the soft portion A2. In addition, the passivation layer 117 and the third interlayer insulation layer 116 may also be partially removed in the rigid portion A1, thereby the top surface of the second interlayer insulation layer 115 in the rigid portion A1.

Next, in FIG. 8D, the planarization layer 118 may be formed on the passivation layer 117 by applying an organic insulating material over substantially the entire surface of the carrier substrate 102 and then may be patterned through a photolithography process to thereby form the contact holes exposing the pad electrode 127, the drain electrode 129, and the second connection electrode 131.

At this time, in the soft portion A2, the planarization layer 118 may be removed to thereby expose the top surface of the second base portion 110b of the soft portion A2, and in the rigid portion A1, the planarization layer 118 may be in contact with the side surfaces of the third interlayer insulation layer 116 and the passivation layer 117 and the top surface of the second interlayer insulation layer 115.

Meanwhile, it is described as an example that the first buffer layer 111, the second buffer layer 112, the gate insulation layer 113, the first interlayer insulation layer 114, and the second interlayer insulation layer 115 of the soft portion A2 are removed in the step of FIG. 8B, but embodiments of the present disclosure are not limited thereto. In other embodiments, the first buffer layer 111, the second buffer layer 112, the gate insulation layer 113, the first interlayer insulation layer 114, and the second interlayer insulation layer 115 of the soft portion A2 are removed together with the planarization layer 118 in the step of FIG. 8D.

Then, the stretchable line 134 may be formed in the rigid portion A1 and the soft portion A2 by depositing a conductive material on the planarization layer 118 and then patterning it through a photolithography process. The stretchable line 134 may be in contact with the auxiliary pad 133 through the contact hole formed in the passivation layer 117 and the planarization layer 118 in the rigid portion A1 and may extend into the soft portion A2 to thereby be in contact with the top surface of the second base portion 110b exposed in the soft portion A2. In this case, the stretchable line 134 may also be in contact with the inclined side surfaces of the first buffer layer 111, the second buffer layer 112, the gate insulation layer 113, the first interlayer insulation layer 114, the second interlayer insulation layer 115, and the planarization layer 118.

Next, in FIG. 8E, the first lower electrode 142 and the second lower electrode 144 may be formed in the rigid portion A1 by depositing a first conductive material on the planarization layer 118 and then patterning it through a photolithography process. The first lower electrode 142 may be in contact with the drain electrode 129 and the second lower electrode 144 may be in contact with the second connection electrode 131 through the contact holes formed in the third interlayer insulation layer 115, the passivation layer 117, and the planarization layer 118.

Here, the first conductive material may migrate due to heat. For example, the first conductive material may include silver (Ag).

Next, in FIG. 8F, the first upper electrode 146 and the second upper electrode 148 may be formed in the rigid portion A1 by depositing a second conductive material on the first lower electrode 142 and the second lower electrode 144 and then patterning it through a photolithography process. The first upper electrode 146 may cover the top and side surfaces of the first lower electrode 142 and may have a plurality of holes exposing the top surface of the first lower electrode 142. The second upper electrode 148 may cover the top and side surfaces of the second lower electrode 144 and may have a plurality of holes exposing the top surface of the second lower electrode 144.

Here, the second conductive material may be a transparent conductive material. For example, the second conductive material may be indium tin oxide (ITO) or indium zinc oxide (IZO).

The first lower electrode 142 and the first upper electrode 146 may constitute the first electrode 140a, and the second lower electrode 144 and the second upper electrode 148 may constitute the second electrode 140b.

Next, in FIG. 8G, the first protrusions 142a and the second protrusions 144a may be formed by applying heat. The material of the first and second lower electrodes 142 and 144 may migrate due to the applied heat and may protrude above the holes of the first and second upper electrodes 146 and 148, thereby forming the first and second protrusions 142a and 144a of the first and second lower electrodes 142 and 144.

Next, in FIG. 8H, a cured adhesive layer 149 may be formed between the first electrode 140a and the second electrode 140b by applying an organic material and first curing it. Here, the adhesive layer 149 may not be completely cured and may have viscosity. For example, the adhesive layer 149 may be formed of an acryl-based, urethane-based, or silicone-based organic material.

Next, in FIG. 8I, the light-emitting element 150 may be transferred on the first electrode 140a, the second electrode 140b, and the adhesive layer 149. Here, the p-electrode 157 of the light-emitting element 150 may be in contact with the first protrusions 142a of the first electrode 140a, and the n-electrode 158 of the light-emitting element 150 may be in contact with the second protrusions 144a of the second electrode 140b. The adhesive layer 149 may be in contact with the protection layer 156 of the light-emitting element 150 in the concave portion between the p-electrode 157 and the n-electrode 158.

Next, in FIG. 6, the adhesive layer 149 may be secondly cured by applying heat and pressure, so that the light-emitting element 150 may be fixed. In this case, the first and second protrusions 142a and 144a may be pressed and be in complete contact with the p-electrode 157 and the n-electrode 158, thereby increasing the contact area.

Then, the carrier substrate 102 and the sacrificial layer 104 may be separated from the base substrate 110. In this case, by irradiating a laser beam from the bottom of the carrier substrate 102, the carrier substrate 102 and the sacrificial layer 104 may be separated.

As such, in the method of manufacturing the stretchable display device according to the first embodiment of the present disclosure, the material of the first and second lower electrodes 142 and 144 may be allowed to protrude, thereby forming the first and second protrusions 142a and 144a.

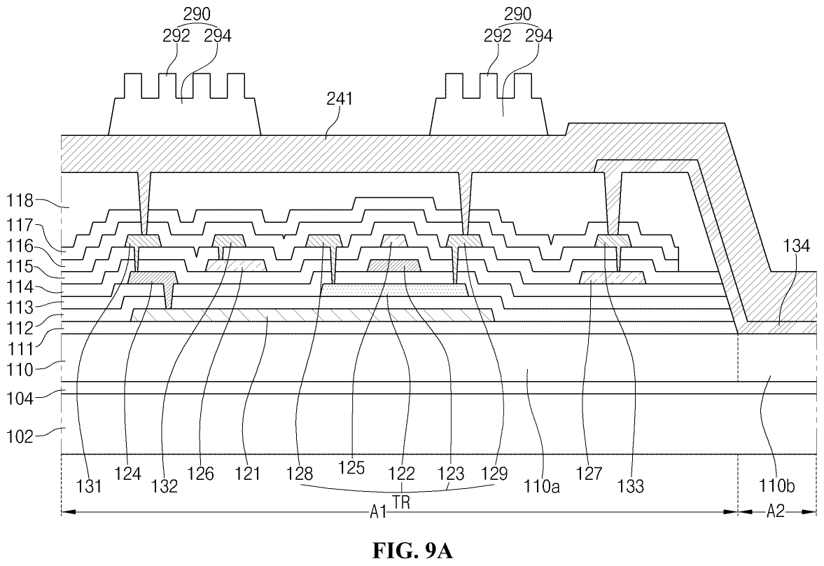

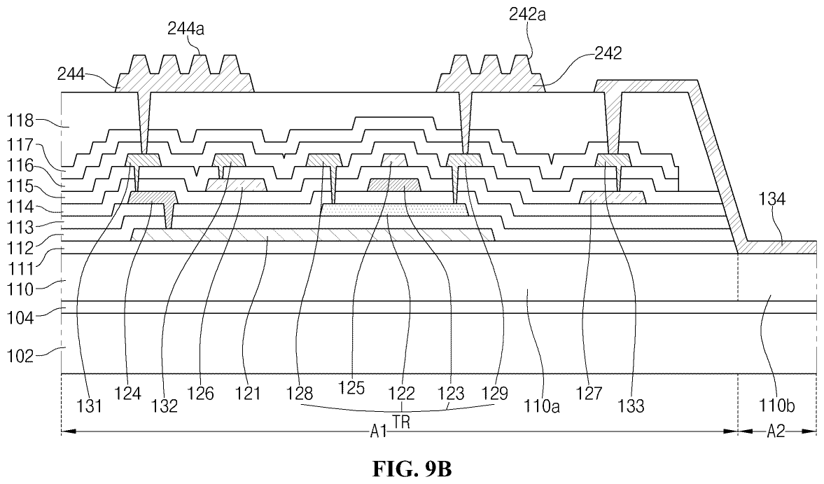

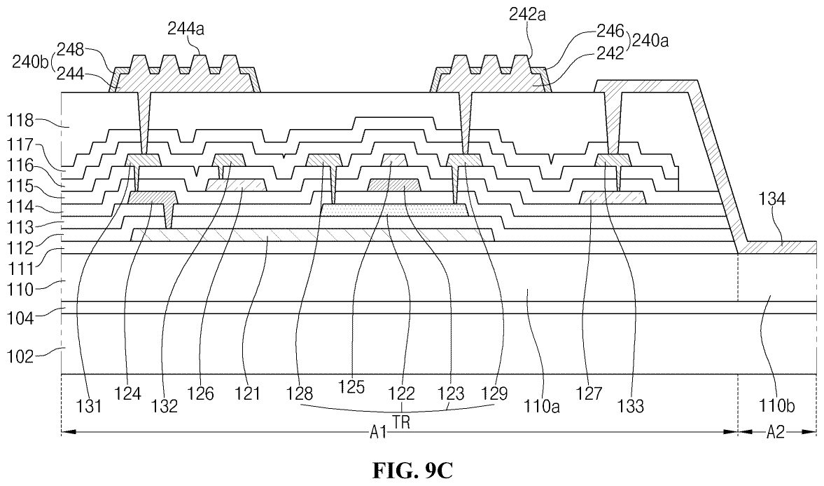

In another embodiment of the present disclosure, the first and second protrusions may be formed by using a halftone mask. A method of manufacturing a stretchable display device according to such an embodiment of the present disclosure will be described with reference to FIGS. 9A to 9C.

FIGS. 9A to 9C are schematic cross-sectional views of a display panel in steps of manufacturing a stretchable display device according to a second embodiment of the present disclosure. The method of manufacturing the stretchable display device according to the second embodiment of the present disclosure includes substantially the same steps as those of the first embodiment, except for the steps of forming the first and second electrodes. The same parts as those of the first embodiment are designated by the same reference signs, and explanation for the same parts may be shortened or omitted.

First, the planarization layer 118 and the stretchable line 134 may be formed over the carrier substrate 102 through the same steps as those of FIGS. 8A to 8D.

Next, in FIG. 9A, a lower electrode layer 241 may be formed on the planarization layer 118 and the stretchable line 134 by depositing a first conductive material. In this case, the lower electrode layer 241 may be formed in both the rigid portion A1 and the soft portion A2.

Then, a photoresist pattern 290 may be formed on the lower electrode layer 241 through a photolithography process where photoresist is applied, exposed to light, and developed. The photoresist pattern 290 may include a first pattern 292 and a second pattern 294. The thickness and height of the first pattern 292 may be greater than the thickness and height of the second pattern 294.

Here, the photoresist may be exposed to light through a halftone mask including a light-blocking part, a light-transmitting part, and a half light-transmitting part. The photoresist may have positive photosensitivity in which a portion exposed to light is removed after developing. Accordingly, the first pattern 292 of the photoresist pattern 290 may correspond to the light-blocking part, and the second pattern 294 may correspond to the half light-transmitting part.

However, embodiments of the present disclosure are not limited thereto. In other embodiments, the photoresist may have negative photosensitivity in which a portion exposed to light remains after developing. In this case, the first pattern 292 of the photoresist pattern 290 may correspond to the light-transmitting part.

Next, in FIG. 9B, the first lower electrode 242 having the first protrusions 242a and the second lower electrode 244 having the second protrusions 244a may be formed by patterning the exposed portions of the lower electrode layer 241 using the photoresist pattern 290 as an etching mask. Then, the photoresist pattern 290 remaining on the first lower electrode 242 and the second lower electrode 244 may be removed.

Here, the first protrusions 242a and the second protrusions 244a may correspond to the first pattern 292 of the photoresist pattern 290.

Next, in FIG. 9C, the first upper electrode 246 and the second upper electrode 248 may be formed in the rigid portion A1 by depositing a second conductive material on the first lower electrode 242 and the second lower electrode 244 and patterning it through a photolithography process. The first upper electrode 246 may have the plurality of holes exposing the first protrusions 242a and may cover the top and side surfaces of the first lower electrode 242. The second upper electrode 248 may have the plurality of holes exposing the second protrusions 244a and may cover the top and side surfaces of the second lower electrode 244.

In other embodiments, the first upper electrode 246 and the second upper electrode 248 may not have the holes and may cover the first protrusions 242a and the second protrusions 244a, respectively.

The first lower electrode 242 and the first upper electrode 246 may constitute the first electrode 240a, and the second lower electrode 244 and the second upper electrode 248 may constitute the second electrode 240b.

Then, by performing the steps of FIGS. 8H to 8I, the adhesive layer 149 may be formed, and the light-emitting element 150 may be attached.

As such, in the method of manufacturing the stretchable display device according to the second embodiment of the present disclosure, the first and second protrusions 242a and 244a may be formed using the halftone mask. Accordingly, the protruding step can be omitted, thereby decreasing the number of the manufacturing processes and reducing the costs compared to the first embodiment.

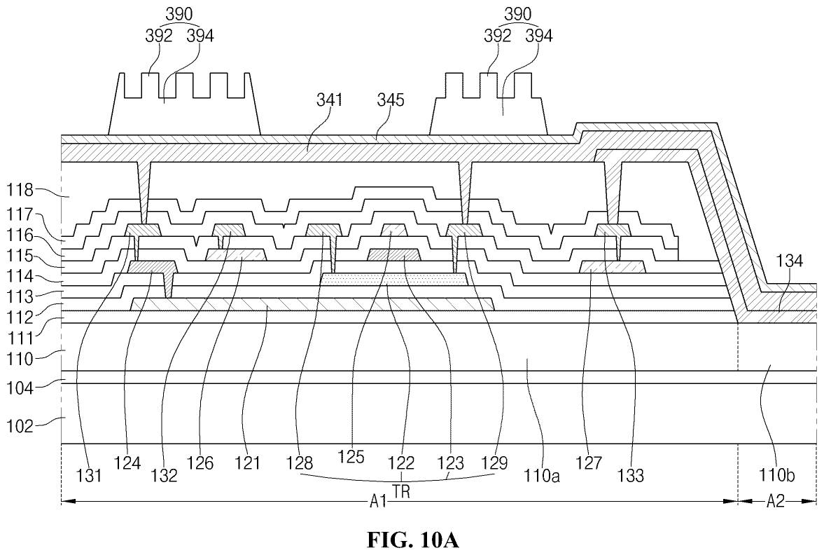

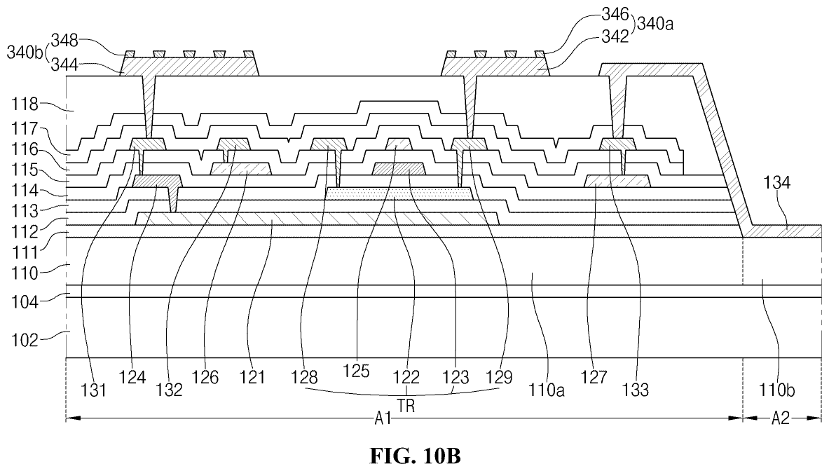

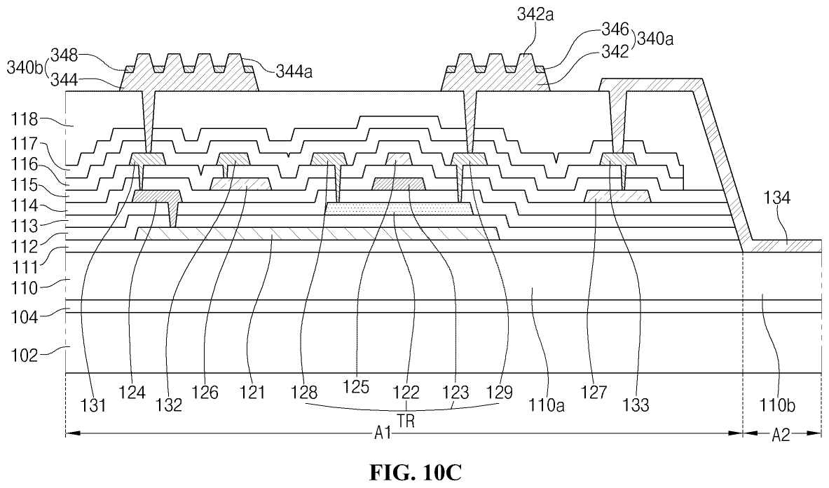

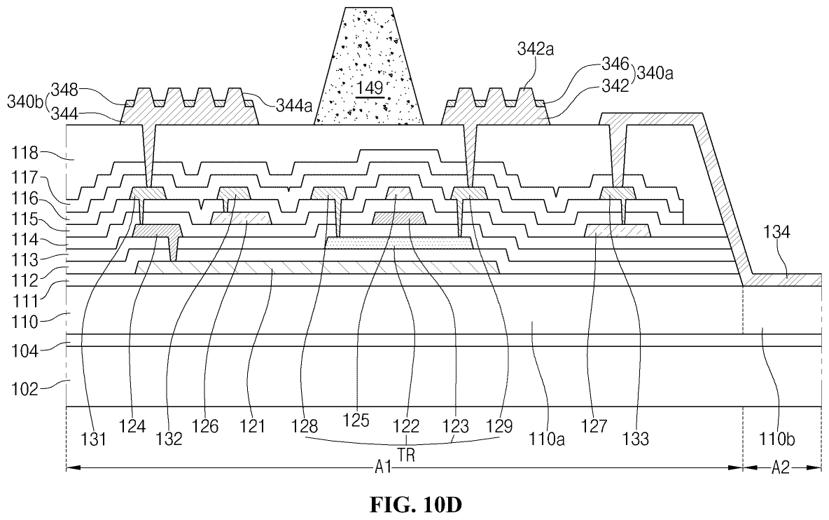

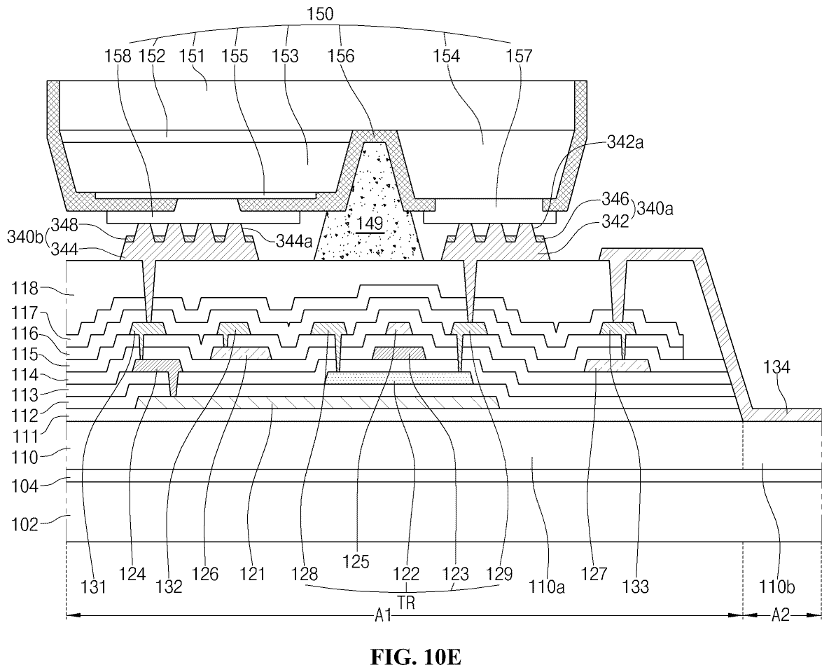

Further, in another embodiment of the present disclosure, the first and second protrusions may be formed by forming a pattern using a halftone mask and then allowing the material of the first and second lower electrodes to protrude. A method of manufacturing a stretchable display device according to such an embodiment of the present disclosure will be described with reference to FIGS. 10A to 10E.

FIGS. 10A to 10E are schematic cross-sectional views of a display panel in steps of manufacturing a stretchable display device according to a third embodiment of the present disclosure. The method of manufacturing the stretchable display device according to the third embodiment of the present disclosure includes substantially the same steps as those of the first and second embodiments, except for the steps of forming the first and second electrodes. The same parts as those of the first and second embodiments are designated by the same reference signs, and explanation for the same parts may be shortened or omitted.

First, the planarization layer 118 and the stretchable line 134 may be formed over the carrier substrate 102 through the same steps as those of FIGS. 8A to 8D.

Next, in FIG. 10A, a lower electrode layer 341 may be formed on the planarization layer 118 and the stretchable line 134 by depositing a first conductive material, and an upper electrode layer 345 may be formed on the lower electrode layer 341 by depositing a second conductive material. In this case, the lower electrode layer 341 and the upper electrode layer 345 may be formed in both the rigid portion A1 and the soft portion A2.

Then, a photoresist pattern 390 may be formed on the upper electrode layer 345 through a photolithography process where photoresist is applied, exposed to light, and developed. The photoresist pattern 390 may include a first pattern 392 and a second pattern 394. The thickness and height of the first pattern 392 may be greater than the thickness and height of the second pattern 394.

Here, the photoresist may be exposed to light through a halftone mask including a light-blocking part, a light-transmitting part, and a half light-transmitting part. The photoresist may have positive photosensitivity in which a portion exposed to light is removed after developing. Accordingly, the first pattern 392 of the photoresist pattern 390 may correspond to the light-blocking part, and the second pattern 394 may correspond to the half light-transmitting part.

However, embodiments of the present disclosure are not limited thereto. In other embodiments, the photoresist may have negative photosensitivity in which a portion exposed to light remains after developing. In this case, the first pattern 392 of the photoresist pattern 390 may correspond to the light-transmitting part.

Next, in FIG. 10B, the first electrode 340a and the second electrode 340b may be formed by patterning the exposed portions of the upper electrode layer 345 and the lower electrode layer 341 using the photoresist pattern 390 as an etching mask. Then, the photoresist pattern 390 remaining on the first electrode 340a and the second electrode 340b may be removed.

The first electrode 340a may include the first lower electrode 342 and the first upper electrode 346, and the second electrode 340b may include the second lower electrode 344 and the second upper electrode 348. The first upper electrode 346 may partially cover the top surface of the first lower electrode 342 and expose the side surface of the first lower electrode 342. The second upper electrode 348 may partially cover the top surface of the second lower electrode 344 and expose the side surface of the second lower electrode 344. The first upper electrode 346 may have a plurality of holes exposing the first lower electrode 342, and the second upper electrode 348 may have a plurality of holes exposing the second lower electrode 344.

Here, the holes of the first upper electrode 346 and the second upper electrode 348 may correspond to the second pattern 394 of the photoresist pattern 390.

Next, in FIG. 10C, the first protrusions 342a and the second protrusions 344a may be formed by applying heat. The material of the first and second lower electrodes 342 and 344 may migrate due to the applied heat and may protrude above the holes of the first and second upper electrodes 346 and 348, thereby forming the first and second protrusions 342a and 344a of the first and second lower electrodes 342 and 344.

Next, in FIG. 10D, a cured adhesive layer 149 may be formed between the first electrode 340a and the second electrode 340b by applying an organic material and first curing it.

Next, in FIG. 10E, the light-emitting element 150 may be transferred on the first electrode 340a, the second electrode 340b, and the adhesive layer 149. Here, the p-electrode 157 of the light-emitting element 150 may be in contact with the first protrusions 342a of the first electrode 340a, and the n-electrode 158 of the light-emitting element 150 may be in contact with the second protrusions 344a of the second electrode 340b. The adhesive layer 149 may be in contact with the protection layer 156 of the light-emitting element 150 in the concave portion between the p-electrode 157 and the n-electrode 158.

Then, the adhesive layer 149 may be secondly cured by applying heat and pressure, so that the light-emitting element 150 may be fixed, and the carrier substrate 102 and the sacrificial layer 104 may be separated from the base substrate 110.

As such, in the method of manufacturing the stretchable display device according to the third embodiment of the present disclosure, the first and second electrodes 340a and 340b may be patterned through the photolithography process using the halftone mask, and the material of the first and second lower electrodes 342 and 344 may be allowed to protrude, thereby forming the first and second protrusions 342a and 344a. Accordingly, one photolithography process can be omitted, thereby decreasing the number of the manufacturing processes and reducing the costs compared to the first embodiment.

In the stretchable display device of the present disclosure, by directly connecting the light-emitting element to the first and second electrodes and fixing the light-emitting element through the adhesive layer between the first and second electrodes, the electrical properties of the light-emitting element can be improved because the contact resistance is relatively small, and the manufacturing costs can be reduced because the anisotropic conducive film is omitted.

Accordingly, by improving the lifetime, the production power consumption can be reduced to achieve the low power consumption.

In addition, the first and second electrodes having the protrusions can be formed by various methods using protruding of the electrode material and/or halftone mask, so that the process can be optimized and the production energy can be reduced.

It will be apparent to those skilled in the art that various modifications and variations can be made in the display device of the present disclosure without departing from the technical idea or scope of the disclosure. Thus, it is intended that the present disclosure cover the modifications and variations of this disclosure provided they come within the scope of the appended claims and their equivalents.

What is claimed is:

1. A stretchable display device, comprising:
a base substrate having a rigid portion and a soft portion;
a stretchable line in the soft portion over the base substrate;
a first electrode and a second electrode in the rigid portion over the base substrate; and
a light-emitting element contacting the first electrode and the second electrode,
wherein the first electrode and the second electrode have a plurality of first protrusions and a plurality of second protrusions, and the light-emitting element is in contact with the plurality of first protrusions and the plurality of second protrusions.

2. The stretchable display device of claim 1, wherein the first electrode includes a first lower electrode and a first upper electrode, and the second electrode includes a second lower electrode and a second upper electrode, and
wherein the first lower electrode has the plurality of first protrusions, and the second lower electrode has the plurality of second protrusions.

3. The stretchable display device of claim 2, wherein the first upper electrode has a plurality of holes that expose the plurality of first protrusions, respectively, and the second upper electrode has a plurality of holes that expose the plurality of second protrusions, respectively.

4. The stretchable display device of claim 3, wherein a width of a top surface of each of the plurality of first protrusions that contact the light-emitting element is greater than a width of a hole from the plurality of holes of the first upper electrode, and a width of a top surface of each of the plurality of second protrusions contacting the light-emitting element is greater than a width of a hole from the plurality of holes of the second upper electrode.

5. The stretchable display device of claim 2, wherein a thickness of the plurality of first protrusions is greater than a thickness of the first upper electrode, and a thickness of the plurality of second protrusions is greater than a thickness of the second upper electrode.

6. The stretchable display device of claim 2, further comprising:
a planarization layer between the base substrate and the first electrode and the second electrode in the rigid portion,
wherein the stretchable line extends into and is on the planarization layer, and the first electrode and the second electrode include a material that is different from a material of the stretchable line.

7. The stretchable display device of claim 6, wherein the first lower electrode and the second lower electrode includes silver, and the first upper electrode and the second upper electrode includes indium tin oxide or indium zinc oxide.

8. The stretchable display device of claim 1, further comprising:
an adhesive layer between the first electrode and the second electrode over the base substrate, the adhesive layer in contact with the light-emitting element.

9. The stretchable display device of claim 8, wherein the light-emitting element has a p-electrode contacting the plurality of first protrusions, an n-electrode contacting the plurality of second protrusions, and a concave portion between the p-electrode and the n-electrode, and
wherein the adhesive layer corresponds to the concave portion.

10. A method of manufacturing a stretchable display device, comprising:
preparing a base substrate having a rigid portion and a soft portion;
forming a stretchable line in the soft portion over the base substrate;
forming a first electrode and a second electrode in the rigid portion over the base substrate; and
transferring a light-emitting element that contacts the first electrode and the second electrode,
wherein forming the first electrode and the second electrode includes forming a plurality of first protrusions and a plurality of second protrusions, and
wherein transferring the light-emitting element includes contacting the light-emitting element with the plurality of first protrusions and the plurality of second protrusions.

11. The method of claim 10, wherein forming the first electrode and the second electrode includes:
forming a first lower electrode and a second lower electrode;
forming a first upper electrode and a second upper electrode on the first lower electrode and the second lower electrode, respectively; and
forming the plurality of first protrusions and the plurality of second protrusions by applying heat.

12. The method of claim 11, wherein the first upper electrode has a plurality of holes that expose the plurality of first protrusions, respectively, and the second upper electrode has a plurality of holes that expose the plurality of second protrusions, respectively.

13. The method of claim 10, wherein forming the first electrode and the second electrode includes:
forming a first lower electrode having the plurality of first protrusions and a second lower electrode having the plurality of second protrusions; and
forming a first upper electrode and a second upper electrode on the first lower electrode and the second lower electrode, respectively.

14. The method of claim 13, wherein the first upper electrode has a plurality of holes that expose the plurality of first protrusions, respectively, and the second upper electrode has a plurality of holes that expose the plurality of second protrusions, respectively.

15. The method of claim 10, wherein forming the first electrode and the second electrode includes:
sequentially forming a lower electrode layer and an upper electrode layer;
forming a first lower electrode, a second lower electrode, a first upper electrode, and a second upper electrode by patterning the lower electrode layer and the upper electrode layer; and
forming the plurality of first protrusions and the plurality of second protrusions by applying heat.

16. The method of claim 15, wherein the first upper electrode has a plurality of holes that expose the plurality of first protrusions, respectively, and the second upper electrode has a plurality of holes that expose the plurality of second protrusions, respectively.
